(19) United States
(12) Patent Application Publication
(10) Pub. No.: US 2026/0176745 A1
(43) Pub. Date: Jun. 25, 2026

(54) METHOD FOR MANUFACTURING PROCESSED SUBSTRATE, METHOD FOR PROCESSING SUBSTRATE, PATTERN FORMATION METHOD, AND CLEANING LIQUID

(71) Applicant: Tokyo Ohka Kogyo Co., Ltd., Kawasaki-shi (JP)

(72) Inventors: Koya Inomata, Kawasaki-shi (JP); Daichi Tanaka, Kawasaki-shi (JP); Kazuya Tajima, Kawasaki-shi (JP)

(21) Appl. No.: 19/124,533

(22) PCT Filed: Nov. 6, 2023
(86) PCT No.: PCT/JP2023/039875

§ 371 Date: Apr. 25, 2025

(30) Foreign Application Priority Data
Nov. 22, 2022 (JP) 2022-186637

(51) Int. Cl. C23C 16/02; B08B 3/08; C11D 7/50; C23C 16/04; C23C 16/455

(52) U.S. Cl. CPC C23C 16/0227; B08B 3/08; C11D 7/5022; C11D 7/5027; C23C 16/04; C23C 16/45525

(57) ABSTRACT

A method for manufacturing a processed substrate having a surface in which at least a part of a region is modified includes a step of exposing a surface of a substrate to a surface modifier containing a compound having a bonding property to the substrate, and a step of cleaning the substrate after the exposure with a cleaning liquid and performing film formation while controlling the compound in a plane direction and a height direction of the substrate to obtain a processed substrate. The cleaning liquid in which a distance Ra between a Hansen solubility parameter of the compound and a Hansen solubility parameter of the cleaning liquid satisfies a relationship of (Ra)²≤128 is selected and used.

### TECHNICAL FIELD

The present invention relates to a method for manufacturing a processed substrate, a method for processing a substrate, a pattern formation method, and a cleaning liquid.

Priority is claimed on Japanese Patent Application No. 2022-186637, filed Nov. 22, 2022, the content of which is incorporated herein by reference.

### BACKGROUND ART

In recent years, with the progress of high integration and miniaturization of semiconductor devices, miniaturization of organic patterns used as masks and inorganic patterns prepared by etching processing has proceeded, and thus the film thickness needs to be controlled at an atomic layer level.

As a method for forming a film, which is thin at an atomic layer level, on a substrate, an atomic layer deposition method (ALD method; hereinafter, also simply referred to as “ALD method”) is known. The ALD method is known to have both high step coverage and film thickness controllability as compared with a typical chemical vapor deposition (CVD) method.

The ALD method is a thin-film forming technology of alternately supplying two kinds of gases having elements constituting a film intended to be formed as main components onto a substrate and repeatedly forming a thin film a plurality of times on the substrate in an atomic layer unit to form a film having a desired thickness.

In the ALD method, a self-control function (self-limit function) of growth in which only one layer or several layers of raw material gas components are adsorbed on a substrate surface while the raw material gases are supplied and the extra raw material gases do not contribute to the growth is used.

For example, in a case where an Al₂O₃ film is formed on a substrate, a raw material gas formed of trimethyl aluminum (TMA) and an oxidizing gas including O are used. Further, in a case where a nitride film is formed on a substrate, a nitride gas is used in place of the oxidizing gas.

In recent years, a method for forming a film on a selected region of a substrate surface using an ALD method has been attempted. For example, after the region of the substrate is partially subjected to water-repellent processing using a surface modifier, an atomic layer is formed on an unprocessed region by the ALD method. In a method for forming a film, control of the film thickness at an atomic layer level, step coverage, and miniaturization of patterning are expected by using the ALD method.

In the method for forming a film on a selected region of a substrate surface, typically, film formation on the water-repellent substrate surface is inhibited by selectively imparting water repellency to a region of the substrate surface. For example, in a case where a film is formed on a selected insulator surface on the substrate surface where the electric conductor surface and the insulator surface are mixed, it is necessary to impart water repellency to the selected electric conductor surface.

For example, Patent Document 1 describes that, on a surface including two or more regions, a self-assembled monolayer film of octadecyl phosphonic acid is formed on surfaces having different materials among adjacent regions of the two or more regions so that the contrast between the regions having different materials is enhanced.

### CITATION LIST

### Patent Document

Patent Document 1: Japanese Unexamined Patent Application, First Publication No. 2021-014631

### SUMMARY OF INVENTION

### Technical Problem

In a case where water repellency is region-selectively imparted to the substrate surface using a surface modifier, and the surplus surface modifier is deposited on a surface modified layer, the modified layer cannot be uniformly formed into a film, which causes a pattern defect.

In addition, Patent Document 1 discloses that, in the method, the surface modifier is cleaned with isopropyl alcohol (IPA) after exposure, but the removability of the surplus surface modifier is poor, and thus there is room for improvement.

The present invention has been made in consideration of the above-described circumstances, and an object thereof is to provide a method for manufacturing a processed substrate having a surface in which at least a part of a region is modified, in which a substrate exposed to a surface modifier is cleaned to remove the surplus surface modifier, and a processed substrate on which the surface modifier is controlled in a plane direction and a height direction to form a film can be obtained, a method for processing a substrate, a pattern formation method, and a cleaning liquid, which can be used in the manufacturing method.

### Solution to Problem

In order to solve the above-described problems, the present invention has adopted the following configurations.

According to a first aspect of the present invention, there is provided a method for manufacturing a processed substrate having a surface in which at least a part of a region is modified, the manufacturing method including: a step of exposing a surface of a substrate to a surface modifier containing a compound (A) having a bonding property to the substrate; and a step of cleaning the substrate after the exposure with a cleaning liquid and performing film formation while controlling the compound (A) in a plane direction and a height direction of the substrate to obtain a processed substrate, in which the cleaning liquid in which a distance Ra between a Hansen solubility parameter of the compound (A) and a Hansen solubility parameter of the cleaning liquid satisfies a relationship of (Ra)²≤128 is selected and used.

According to a second aspect of the present invention, there is provided a method for processing a substrate, including: a step of exposing a surface of a substrate to a surface modifier containing a compound (A) having a bonding property to the substrate; and a step of cleaning the substrate after the exposure with a cleaning liquid and performing film formation while controlling the compound (A) in a plane direction and a height direction of the substrate, in which the cleaning liquid in which a distance Ra between a Hansen solubility parameter of the compound (A) and a Hansen solubility parameter of the cleaning liquid satisfies a relationship of (Ra)²<128 is selected and used.

According to a third aspect of the present invention, there is provided a pattern formation method including: a step of forming an atomic layer on a surface of a region of the processed substrate, which is manufactured by the method for manufacturing a processed substrate according to the first aspect, where the surface modifier is not formed into a film, by forming a thin film using a vapor deposition method.

According to a fourth aspect of the present invention, there is provided a cleaning liquid which is used in the method for manufacturing a processed substrate according to the first aspect or in the method for processing a substrate according to the second aspect, the cleaning liquid including: at least one organic solvent selected from the group consisting of decane, tetradecane, cyclohexane, propylene glycol monomethyl ether acetate, isobutanol, 1-octanol, 2-ethyl-1-hexanol, dibutyl ether, acetone, cyclopentanone, 2,6-dimethyl-4-heptanone, and propylene glycol monomethyl ether.

### Advantageous Effects of Invention

According to the present invention, it is possible to provide a method for manufacturing a processed substrate having a surface in which at least a part of a region is modified, in which a substrate exposed to a surface modifier is cleaned to remove the surplus surface modifier, and a processed substrate on which the surface modifier is controlled in a plane direction and a height direction to form a film can be obtained, a method for processing a substrate, a pattern formation method, and a cleaning liquid, which can be used in the manufacturing method.

### BRIEF DESCRIPTION OF DRAWINGS

FIG. 1 A schematic view showing a state after a surface of a substrate is exposed to a surface modifier (after an exposing step).

FIG. 2 A schematic view showing a state before and after the substrate after the exposing step is cleaned with a cleaning liquid.

FIG. 3A An image (observation range: 1 μm×1 μm) of a substrate surface immediately after the exposing step, which is observed with an atomic force microscope (AFM).

FIG. 3B An AFM observation image (observation range: 1 μm×1 μm) of the surface of the processed substrate manufactured in Example 11.

FIG. 3C An AFM observation image (observation range: 1 μm×1 μm) of the surface of the processed substrate manufactured in Comparative Example 1.

### DESCRIPTION OF EMBODIMENTS

Hereinafter, embodiments of the present invention will be described in detail below, but the present invention is not limited to the embodiments described below, and modifications can be made as appropriate within the scope of the object of the present invention.

### (Method for Manufacturing Processed Substrate)

A method for manufacturing a processed substrate according to the first aspect of the present invention is a method for manufacturing a processed substrate having a surface in which at least a part of a region is modified.

The method for manufacturing a processed substrate includes a step of exposing a surface of a substrate to a surface modifier containing a compound (A) having a bonding property to the substrate (hereinafter, also referred to as “exposing step”) and a step of cleaning the substrate after the exposure with a cleaning liquid and performing film formation while controlling the compound (A) in a plane direction and a height direction of the substrate to obtain a processed substrate (hereinafter, also referred to as “cleaning step”).

In the method for manufacturing a processed substrate, the cleaning liquid in which a distance Ra between a Hansen solubility parameter of the compound (A) and a Hansen solubility parameter of the cleaning liquid satisfies a relationship of (Ra)²≤128 is selected and used.

FIG. 1 is a schematic view showing a state after the surface of the substrate is exposed to the surface modifier (after the exposing step).

A substrate 10 includes a region A and a region B.

The surface modifier contains a compound (A) 20 having a bonding property to the region B of the substrate 10.

In FIG. 1, a surface modifier layer 224 that covers the entire surface of the region B of the substrate 10 is formed on the substrate 10. The surface modifier layer 224 is formed of a monolayer portion 22 in which the compound (A) 20 is directly bonded to the surface of the region B of the substrate 10, and a surplus portion 24 in which the compound (A) 20 is deposited on the monolayer portion 22.

The surplus portion 24 protrudes onto the region A of the substrate 10. In such a state, in a case where an atomic layer is intended to be formed on the region A of the substrate 10, the film formation is inhibited, and a layer C (enclosed by a broken line) in which a defect d occurs in a part thereof is formed.

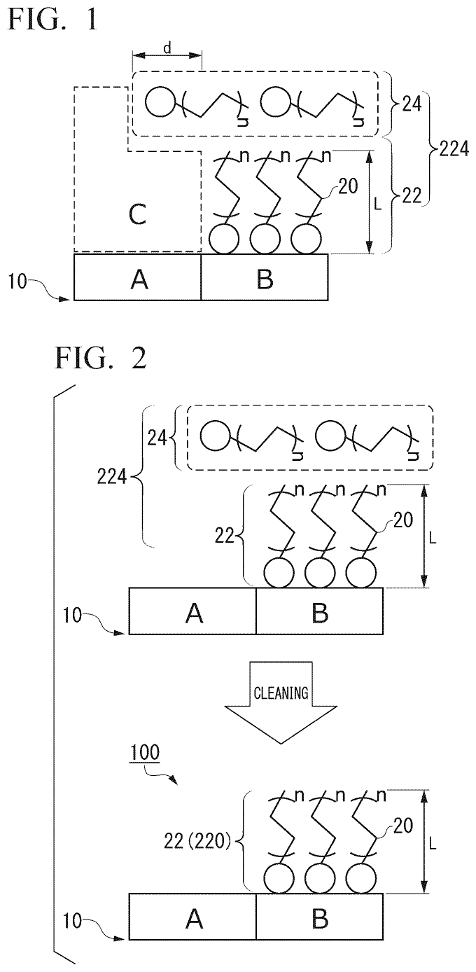

FIG. 2 is a schematic view showing a state before and after the substrate after the exposing step is cleaned with a cleaning liquid.

In a processed substrate 100 after being cleaned, a surface modifier layer 220 that covers the entire surface of the region B of the substrate 10 is formed on the substrate 10. The surplus portion 24 is cleaned and removed by the cleaning liquid, and the surface modifier layer 220 is formed of only the monolayer portion 22 in which the compound (A) 20 is directly bonded to the surface of the region B of the substrate 10. That is, the processed substrate 100 on which the compound (A) 20 is controlled in the plane direction and the height direction of the substrate 10 to form a film is obtained.

The expression “the compound (A) is controlled in the plane direction and the height direction of the substrate to form a film” denotes that molecules of the compound (A) are arranged on a surface of a specific region of the substrate to cover the entire surface of the specific region, and a film having a certain thickness is formed without covering a region adjacent to the specific region. In FIG. 2, in the processed substrate 100, the molecules of the compound (A) are arranged on the surface of the region B in the substrate 10 to cover the entire surface of the region B, and a film (surface modifier layer 220, monolayer portion 22) having a certain thickness L is formed without covering the region A adjacent to the region B.

In such a state, in a case where an atomic layer is intended to be formed on the region A of the substrate 10, a desired atomic layer can be easily formed without inhibiting the film formation.

According to the method for manufacturing a processed substrate according to the first aspect, the processed substrate 100 as shown in FIG. 2 can be manufactured.

Hereinafter, one embodiment of such a method for manufacturing a processed substrate will be described.

### <Exposing Step>

In the exposing step of the present embodiment, the surface of the substrate is exposed to the surface modifier containing a compound (A) having a bonding property to the substrate.

### <<in Regard to Substrate>>

A substrate used for preparing a semiconductor device is an exemplary example of the substrate to be processed in the present embodiment. Examples of the substrate include a silicon (Si) substrate, a silicon nitride (SiN) substrate, a silicon oxide (SiOx) film substrate, a tungsten (W) substrate, a cobalt (Co) substrate, a titanium nitride (TiN) substrate, a tantalum nitride (TaN) substrate, a germanium (Ge) substrate, a silicon germanium (SiGe) substrate, an aluminum (Al) substrate, a nickel (Ni) substrate, a ruthenium (Ru) substrate, and a copper (Cu) substrate.

Examples of “surface of the substrate” include a surface of a substrate, a surface of an inorganic pattern or an organic pattern provided on a substrate, and a surface of an inorganic layer or an organic layer, which is not patterned.

Examples of the inorganic pattern provided on a substrate include a pattern formed by preparing an etching mask on a surface of an inorganic layer present on a substrate using a photoresist method and performing etching processing. Examples of the inorganic layer include an oxide film of an element constituting a substrate, and a film or a layer of an inorganic substance such as SiN, SiOx, W, Co, TiN, TaN, Ge, SiGe, Al, Al₂O₃, Ni, Ru, or Cu formed on a surface of a substrate, in addition to a substrate,

Such a film or layer is not particularly limited, and examples thereof include a film or a layer of an inorganic substance formed in the process of preparation of a semiconductor device.

Examples of the organic pattern provided on a substrate include a resin pattern formed on a substrate using a photoresist or the like according to a photolithography method. Such an organic pattern can be formed by, for example, forming an organic layer which is a photoresist film on a substrate, exposing the organic layer through a photomask, and developing the organic layer. The organic layer may be an organic layer provided on a surface or the like of a laminated film provided on a surface of a substrate in addition to a surface of a substrate. Such an organic layer is not particularly limited, and examples thereof include a film of an organic substance provided to form an etching mask in the process of preparing a semiconductor device.

In the method for manufacturing a processed substrate according to the present embodiment, the surface of the substrate to be processed may include one or two or more regions. In a case where the surface to be processed includes two or more regions, at least one of the two or more regions includes a substrate surface, and proximate regions in the two or more regions may be formed of different materials.

In FIG. 1, the substrate 10 includes the region A and the region B. The surface of the substrate 10 to be processed is exposed to the surface modifier, and thus the compound (A) 20 is selectively adsorbed on the surface of the region B of the substrate 10. In this manner, the contact angles of water with respect to the surfaces of the regions can be made different between the region A and the region B of the substrate 10.

### <<in Regard to Surface Modifier>>

In the present embodiment, the surface modifier contains a compound (A) (hereinafter, also referred to as “component (A)”) having a bonding property to a substrate.

In FIG. 1, a surface modifier containing the compound (A) 20 having bonding property to the region B of the substrate 10 is used.

The component (A) is not particularly limited as long as the component (A) has a bonding property to a substrate to be selected, but for example, a component (A) containing a thiol group is preferable in a case where a copper (Cu) or cobalt (Co) substrate is used, a component (A) containing a phosphonic acid group is preferable in a case where a tungsten (W), copper (Cu), cobalt (Co), Al₂O₃, or TiN substrate is used, a component (A) containing an amino group is preferable in a case where a TiN substrate is used, a component (A) containing a carboxylic acid group is preferable in a case where a cobalt (Co) substrate is used, and a component (A) containing a chlorosilane group or an alkoxysilane group is preferable in a case where a SiO₂ substrate is used.

As the component (A) in a case where a copper (Cu) or cobalt (Co) substrate is used, an alkylthiol compound is preferable. Among alkylthiol compounds, a linear or branched alkylthiol is particularly preferable, an alkylthiol having 1 to 45 carbon atoms is preferable, an alkylthiol having 5 to 30 carbon atoms is more preferable, and an alkylthiol having 10 to 25 carbon atoms is still more preferable.

Specific examples of the linear or branched alkylthiol include octadecanethiol, hexadecanethiol, tetradecanethiol, dodecanethiol, and decanethiol. Among these, octadecanethiol is preferable.

The surface modifier may contain a component other than the component (A) in addition to the component (A).

The content of the component (A) in the surface modifier is preferably 90% by mass or greater, more preferably 95% by mass or greater, and still more preferably 99% by mass or greater, and may be 100% by mass with respect to the total mass of the surface modifier.

### [Operation of Exposing Step]

In the exposing step of the present embodiment, the surface of the substrate 10 is exposed to the above-described surface modifier.

A method of exposing the surface of the substrate to the surface modifier containing the component (A) is not particularly limited, and examples thereof include a method of exposing the surface of the substrate to a surface modifier (typically, a surface modifier in a liquid state) which may contain a solvent by means of an immersion method, a coating method such as a spin coating method, a roll coating method, or a doctor blade method, or the like.

The exposure temperature is, for example, 10° C. or higher and 90° C. or lower, preferably 20° C. or higher and 80° C. or lower, and more preferably 20° C. or higher and 30° C. or lower.

From the viewpoint of selective surface modification between regions formed of different materials on the substrate surface, the exposure time is preferably 20 seconds or longer, more preferably 30 seconds or longer, and still more preferably 45 seconds or longer. The upper limit of the exposure time is not particularly limited, but is, for example, 2 hours or shorter, typically 1 hour or shorter, preferably 5 minutes or shorter, more preferably 2 minutes or shorter, and particularly preferably 1 minute or shorter.

In the substrate after the exposure to the surface modifier, the component (A) contained in the surface modifier is region-selectively adsorbed depending on the material of each region of the substrate surface.

In FIG. 1, the compound (A) 20 is adsorbed on the entire surface of the region B of the substrate 10, and the surface modifier layer 224 formed of the monolayer portion 22 and the surplus portion 24 in which the compound (A) 20 is deposited on the monolayer portion 22 is formed. The surplus portion 24 protrudes onto the region A of the substrate 10.

The contact angle of the substrate surface after the exposure to the surface modifier with respect to water can be set to be, for example, 50° or greater and 140° or less.

The contact angle of the substrate surface in the region where the component (A) is adsorbed with respect to water can be set to 50° or greater by controlling the material of the substrate surface, the kind and the used amount of the component (A) contained in the surface modifier, the exposure conditions, and the like. In the present embodiment, the contact angle of the substrate surface in the region where the component (A) is adsorbed with respect to water is preferably 60° or greater, more preferably 70° or greater, and still more preferably 90° or greater. The upper limit of the contact angle of the substrate surface in the region where the component (A) is adsorbed with respect to water is not particularly limited, but is, for example, 140° or less and typically 130° or less.

The contact angle with respect to water is measured, for example, dropping a pure water liquid droplet onto the substrate surface using a contact angle measuring device after a predetermined time has elapsed.

### <Cleaning Step>

In the cleaning step of the present embodiment, the substrate after the exposing step is cleaned with a cleaning liquid and performing film formation while controlling the component (A) in the plane direction and the height direction of the substrate to obtain a processed substrate.

### <<in Regard to Cleaning Liquid>>

In the cleaning step, a cleaning liquid in which the distance Ra between the Hansen solubility parameter of the component (A) and the Hansen solubility parameter satisfies a relationship of (Ra)²≤128 is selected and used.

From the viewpoint of removal performance of the surplus surface modifier, it is preferable that (Ra)² satisfies (Ra)²≤126. From the viewpoint of the removal performance of the surplus surface modifier, the lower limit of (Ra)² is preferably 0≤(Ra)².

The distance Ra between the Hansen solubility parameter of the component (A) and the Hansen solubility parameter of the cleaning liquid is calculated by Mathematical Equation (1) using the Hansen solubility parameters (δ_{dA}, δ_{pA}, δ_{hA}) of the component (A) and the Hansen solubility parameters (δ_{ds}, δₚₛ, δ_{hA}) of the cleaning liquid, which are represented by three-dimensional coordinates.

(Ra)²=(δ_{dS}−δ_{dA})²+(δ_{pS}-δ_{pA})²+(δ_{hS}-δ_{hA})² Mathematical Equation (1)

[Here, δ_{dS} and δ_{dA} are dispersion terms, δ_{pS} and δ_{pA} are polarity terms, and δ_{hS} and δ_{hA} are hydrogen bond terms.]

The Hansen solubility parameter can be calculated, for example, from predetermined parameters based on solubility parameters and aggregation properties described by Charles Hansen in “Hansen Solubility Parameters: A User's Handbook” by Charles M. Hansen, and “The CRC Handbook and Solubility Parameters and Cohesion Parameters,” (1999) edited by CRC Press (2007) and Allan F. M. Barton (1999).

The Hansen solubility parameter is theoretically calculated as a numerical constant and is a useful tool for predicting the ability of a solvent material to dissolve a particular solute.

The Hansen solubility parameters can be a measure of the overall strength and selectivity of a material by combining the following three experimentally and theoretically derived Hansen solubility parameters (that is, δ_{d}, δₚ, and δₕ). The Hansen solubility parameter is in units of MPa^{0.5} or (J/cc)^{0.5}.
δ_{d}: Energy derived from intermolecular dispersion force (dispersion term)
δₚ: Energy derived from intermolecular polar force (polarity term)
δₕ: Energy derived from intermolecular hydrogen bond force (hydrogen bond term)

The Hansen solubility parameters of the component (A) and the cleaning liquid can be calculated by software such as “Molecular Modeling Pro”, version 5.1.9 (ChemSW, Fairfield CA, www.chemsw.com), Hansen Solubility from Dynacomp Software, and HSPiP.

In the present embodiment, a cleaning liquid containing an organic solvent can be used as the cleaning liquid. The organic solvent here may be used alone or in combination of two or more kinds thereof.

In a case where the cleaning liquid contains two or more kinds of organic solvents, the Hansen solubility parameters (δ_{dS}, δ_{pS}, δ_{hS}) of the cleaning liquids can be calculated from the mixing volume ratio of each of the organic solvents.

For example, in a case where an organic solvent (S1) and an organic solvent (S2) described below are used in combination, the Hansen solubility parameters of the cleaning liquids can be calculated by Equations (1) to (3) in a case where the mixing volume ratio of each of the components is a:b (S1:S2=a:b).

$${δ}_{dS} = ( a * {δ}_{dS 1} + b * {δ}_{dS 2} ) / ( a + b ) \qquad ( 1 )$$

$${δ}_{pS} = ( a * {δ}_{pS 1} + b * {δ}_{pS 2} ) / ( a + b ) \qquad ( 2 )$$

$${δ}_{hS} = ( a * {δ}_{hS 1} + b * {δ}_{hS 2} ) / ( a + b ) \qquad ( 3 )$$

A cleaning liquid containing an organic solvent (S1) (hereinafter, also referred to as “component (S1)”) selected from the group consisting of a polar solvent and a hydrocarbon-based solvent can be suitably used as the cleaning liquid.

Examples of the polar solvent in the component (S1) include a ketone-based solvent, an ester-based solvent, an alcohol-based solvent, and an ether-based solvent.

The ketone-based solvent has preferably 3 or more carbon atoms, and examples thereof include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetylcarbinol, acetophenone, methyl naphthyl ketone, isophorone, and propylene carbonate, and acetone, cyclopentanone, or 2,6-dimethyl-4-heptanone is preferable.

The ester-based solvent has preferably 6 or more carbon atoms, and examples thereof include propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, and 3-methyl-3-methoxybutyl acetate. Among these, propylene glycol monomethyl ether acetate is preferable.

The alcohol-based solvent has preferably 4 or more carbon atoms, and examples thereof include alcohols such as n-butyl alcohol, sec-butyl alcohol, tert-butyl alcohol, isobutyl alcohol, 4-methyl-2-pentanol (methyl isobutyl carbinol; MIBC), n-hexyl alcohol, n-heptyl alcohol, n-octyl alcohol, and n-decanol, glycol-based solvents such as diethylene glycol and triethylene glycol, and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethylbutanol. Among these, isobutanol, 1-octanol, 2-ethyl-1-hexanol, or 1-methoxy-2-propanol is preferable.

The ether-based solvent has preferably 8 or more carbon atoms, and examples thereof include dibutyl ether and dipentyl ether, in addition to the above-described glycol ether-based solvent. Among these, dibutyl ether is preferable.

As the hydrocarbon-based solvent, for example, an alkane having 6 or more carbon atoms is preferable, a linear or cyclic alkane is more preferable, and examples thereof include a linear alkane such as hexane, octane, decane, or undecane, and a cyclic alkane such as cyclohexane, cycloheptane, cyclooctane, or cyclodecane. Among these, decane, tetradecane, and cyclohexane are preferable, and decane and tetradecane are more preferable.

Among the examples, a cleaning liquid containing an organic solvent selected from the group consisting of a ketone-based solvent, an ester-based solvent, an alcohol-based solvent, an ether-based solvent, and a hydrocarbon-based solvent is more preferable, and a cleaning liquid containing at least one organic solvent selected from the group consisting of an alkane having 6 or more carbon atoms, an alkylene glycol monoalkyl ether acetate having 6 or more carbon atoms, an alcohol having 4 or more carbon atoms, an ether having 8 or more carbon atoms, and a ketone having 3 or more carbon atoms is still more preferable as the cleaning liquid.

The cleaning liquid may contain an organic solvent (S2) (hereinafter, also referred to as “component (S2)”) other than the component (S1). The component (S2) is not particularly limited, and an organic solvent having a miscibility with the component (S1) can be used.

The content of the component (S1) in the cleaning liquid is preferably 70% by mass or greater, more preferably 80% by mass or greater, still more preferably 90% by mass or greater, particularly preferably 95% by mass or greater, and may be 100% by mass with respect to the total mass of the cleaning liquid.

### [Operation of Cleaning Step]

In the cleaning step of the present embodiment, the substrate after the exposing step is cleaned with a cleaning liquid.

A method of cleaning the substrate after the exposing step with a cleaning liquid is not particularly limited, and specific examples thereof include a dip method of immersing the substrate in a cleaning liquid filling a cleaning tank, a spin method of allowing the substrate to rotate at a high speed while circulating a cleaning liquid onto the substrate from a nozzle, and a spray method of spraying a liquid onto the substrate for cleaning. Examples of a device for performing such cleaning include a batch-type cleaning device that cleans a plurality of substrates accommodated in a cassette at the same time, and a sheet-type cleaning device that cleans one substrate mounted on a holder.

The temperature condition during the cleaning is, for example, 10° C. or higher and 90° C. or lower, preferably 20° C. or higher and 80° C. or lower, and more preferably 20° C. or higher and 30° C. or lower.

From the viewpoint of the removal performance of the surplus surface modifier, the cleaning time is preferably 20 seconds or longer, more preferably 30 seconds or longer, and still more preferably 45 seconds or longer. The upper limit of the cleaning time is not particularly limited, but is, for example, 5 minutes or shorter, typically 2 minutes or shorter, and preferably 1 minute or shorter.

In the cleaning step of the present embodiment, a processed substrate in which the component (A) is controlled in the plane direction and the height direction of the substrate to form a film after cleaning with the cleaning liquid is obtained.

In the processed substrate 100 after being cleaned as shown in FIG. 2, the surface modifier layer 220 formed of only the monolayer portion 22 covering the entire surface of the region B of the substrate 10 is formed on the substrate 10. The surplus portion 24 that is deposited on the monolayer portion 22 and protrudes onto the region A of the substrate 10 before cleaning is cleaned and removed by the cleaning liquid.

In the embodiment of the method for manufacturing a processed substrate described above, a processed substrate having a surface in which at least a part of a region is modified can be manufactured by the method including a step of exposing a surface of the substrate to a surface modifier containing a compound (A) having a bonding property to the substrate, and a step of cleaning the substrate after the exposure with a cleaning liquid and performing film formation while controlling compound (A) in the plane direction and the height direction of the substrate obtain a processed substrate.

According to the manufacturing method of the present embodiment, the substrate exposed to the compound (A) is cleaned with the cleaning liquid in which the distance Ra between the Hansen solubility parameter of the compound (A) and the Hansen solubility parameter of the cleaning liquid satisfies a relationship of (Ra)²≤128 is used, and thus a processed substrate on which the compound (A) is controlled to in the plane direction and the height direction of the substrate form a film can be obtained,

In the processed substrate obtained in this manner, in a case where an atomic layer is intended to be formed on a specific region of a substrate where the compound (A) is not formed into a film, a desired atomic layer can be easily formed without inhibiting the film formation.

In the processed substrate manufactured by the manufacturing method of the present embodiment, the film formation of the compound (A) controlled in the plane direction and the height direction of the substrate can be confirmed as follows.

The film formation of the compound (A) controlled in the plane direction of the substrate can be confirmed by measuring “contact angle of water” on the processed surface of the substrate. The expression “contact angle of water” here is measured, for example, by dropping a pure water liquid droplet onto the surface of the substrate using a contact angle measuring device after a predetermined time has elapsed.

In a case where “contact angle of water” on the processed surface of the substrate does not substantially change between after the substrate surface is exposed to the surface modifier and after the substrate is cleaned with the cleaning liquid, it can be determined that the compound (A) is controlled in the plane direction of the substrate to form a film.

In the processed substrate manufactured by the manufacturing method of the present embodiment, “contact angle of water” on the processed surface of the substrate is, for example, 50° or greater and 140° or less, preferably 60° or greater and 130° or less, more preferably 70° or greater and 130° or less, and still more preferably 90° or greater and 130° or less.

The film formation of the compound (A) controlled in the height direction of the substrate can be confirmed by measuring the abundance (residual rate) of the compound (A) present at a height greater than a certain value from the substrate surface. The expression “abundance (residual rate) of the compound (A) here” is, for example, an area ratio of molecules of the compound (A) covering the monolayer surface, which is obtained by observing the processed substrate from above using an atomic force microscope (AFM), and detecting the molecules of the compound (A) present (that is, deposited on the monolayer) at a height greater than the thickness of the monolayer, in which the molecules of the compound (A) formed on the substrate are arranged, from the substrate surface.

It can be determined that as “abundance (residual rate)” of the “compound (A)” in the processed surface of the substrate decreases, the cleaning removability of the compound (A) by the cleaning liquid increases, and the compound (A) is controlled in the height direction of the substrate to form a film.

In the processed substrate manufactured by the manufacturing method of the present embodiment, the expression “residual rate of the compound (A)” on the processed surface of the substrate is lower than that in a case where, for example, isopropanol (IPA) for general purpose in the related art is used as the cleaning liquid. For example, in a case where a copper substrate is used as the substrate and octadecanethiol (ODT) is used as the compound (A), “residual rate of the compound (A)” on the processed surface of the substrate is less than 8.2%, preferably 7.5% or less, more preferably 6% or less, and still more preferably 5% or less.

### In Regard to Other Embodiments

In the above-described method for manufacturing a processed substrate of the embodiment, a case where the manufacturing method includes an exposing step and a cleaning step has been described, but the method for manufacturing a processed substrate according to the first aspect of the present invention is not limited thereto, and may further include other steps other than the exposing step and the cleaning step as necessary, Examples of the other steps include a preprocessing step, a surface processing step, a rinsing step, and a drying step.

In regard to preprocessing step:

In the preprocessing step, the preprocessing of the substrate surface is performed. Processing that enables a hydroxyl group to be applied to the substrate surface is preferable as the preprocessing of the substrate surface. Examples of the preprocessing method include ozone processing and processing with an oxidizing agent for preprocessing described below. From the viewpoint of improving the adsorptivity of the surface modifier to the substrate surface, at least one selected from the group consisting of hydrogen peroxide and perhalic acid is preferable as the oxidizing agent for preprocessing.

The processing temperature of the preprocessing is not particularly limited, but is typically in a range of 10° C. to 35° C., preferably in a range of 15° C. to 30° C., and more preferably in a range of 20° C. to 25° C. In a case where the processing temperature of the preprocessing is in the above-described preferable ranges, the natural oxide film on the substrate surface is likely to be removed, and a hydroxyl group is likely to be applied to the substrate surface.

The processing time of the preprocessing is not particularly limited, but is typically in a range of 10 seconds to 10 minutes, preferably in a range of 20 seconds to 5 minutes, and more preferably in a range of 30 seconds to 3 minutes, In a case where the processing time of the preprocessing is in the above-described preferable ranges, the natural oxide film on the substrate surface is likely to be removed, and a hydroxyl group is likely to be applied to the substrate surface.

### In Regard to Surface Processing Step:

In the surface processing step, the substrate surface before the exposing step is processed with diluted hydrofluoric acid by using a known method. By further providing a surface processing step before the exposing step, residues derived from organic substances adhering to the substrate surface can be removed, and the film-forming property of the surface modifier in the plane direction of the substrate can be improved.

### In Regard to Rinsing Step:

After the exposing step, the exposed substrate may be cleaned (for example, cleaned with water, ion exchange water, an activator rinse, or the like) as necessary.

For example, as the cleaning of the substrate surface having an inorganic pattern or an organic pattern, which is performed as necessary, a cleaning liquid that has been used in the related art for cleaning processing of an inorganic pattern or an organic pattern can be employed. Examples of the cleaning liquid for the cleaning processing of an inorganic pattern include sulfuric acid/hydrogen peroxide water (SPM) and ammonia/hydrogen peroxide water (APM), and examples of the cleaning liquid for the cleaning processing of an organic pattern include water and an activator rinse.

### In Regard to Drying Step:

In the drying step, the substrate is dried, In the method for manufacturing a processed substrate according to the present aspect, a drying step may be further provided after the exposing step or the cleaning step. The cleaning liquid remaining on the substrate can be efficiently removed by providing the drying step.

A method for drying the substrate is not particularly limited, and a known method such as spin drying, heat drying, hot air drying, or vacuum drying can be used. Suitable examples thereof include spin drying under a condition of blowing inert gas (such as nitrogen gas).

In addition, the dried substrate after the exposure may be additionally subjected to heat processing at 100° C. or higher and 300° C. or lower as necessary.

In the method for manufacturing a processed substrate according to the present aspect, for example, two kinds of surface modifiers may be used. In the embodiment in a case where two kinds of surface modifiers are used, in a case where a substrate including a region A and a region B is used, the region A is surface-modified by exposing the region A of the substrate to a first surface modifier, and the exposed substrate is cleaned with an appropriate cleaning liquid satisfying the relationship of the present invention. Thereafter, the region B is surface-modified by exposing the region

B of the cleaned substrate to a second surface modifier, and the substrate after the second exposure is cleaned with an appropriate cleaning liquid satisfying the relationship of the present invention, in the same manner as described above. As described above, even in a case where two or more kinds of surface modifiers are used, a processed substrate in which each region of the substrate is modified with different surface modifiers can be obtained by repeating the exposing step and the cleaning step.

In the method for manufacturing a processed substrate according to the above-described embodiment, the surface of the substrate 10 to be processed is exposed to the surface modifier, and thus the compound (A) 20 is selectively adsorbed on the surface of the region B of the substrate 10. In this manner, the contact angles of water with respect to the surfaces of the regions can be made different between the region A and the region B of the substrate 10.

In the substrate that can be used in the method for manufacturing a processed substrate according to the present aspect, examples of a region where the contact angle of water tends to be higher (preferably, the surface free energy is lower) than that of the other regions between two or more regions in the substrate include a region formed of an electric conductor.

The electric conductor is not particularly limited as long as the electric conductor is a material having electroconductivity. Examples of the electric conductor include a material having a metal atom. Examples of the electric conductor include a metal (for example, a single metal element), an alloy, and a metal compound (for example, a nitride). In a case where the electric conductor is a metal, the electric conductor surface is a metal surface. In a case where the electric conductor is an alloy, the electric conductor surface is an alloy surface. In a case where the electric conductor is a metal compound, the electric conductor surface is a surface of an electroconductive metal compound.

Examples of the metal contained in the metal surface include at least one selected from the group consisting of tungsten (W), cobalt (Co), aluminum (Al), titanium nitride (TiN), tantalum nitride (TaN), nickel (Ni), ruthenium (Ru), and copper (Cu). Among these, the metal surface contains preferably at least one selected from the group consisting of tungsten, ruthenium, copper, and cobalt and more preferably at least one selected from the group consisting of tungsten and ruthenium. The region having a substrate surface may be a region formed of a substrate containing these metals.

The electric conductor surface may be subjected to preprocessing with an oxidizing agent. Examples of the oxidizing agent for preprocessing the electric conductor surface (hereinafter, referred to as “oxidizing agent for preprocessing”) include an oxidizing agent capable of removing a natural oxide film present on the electric conductor surface and applying a hydroxyl group to the electric conductor surface. Examples of the oxidizing agent for preprocessing include a peroxide such as hydrogen peroxide, perhalic acid such as periodic acid, and oxo acid such as nitric acid or hypochlorous acid.

Among these, from the viewpoint of the adsorptivity of the compound (A), at least one selected from the group consisting of hydrogen peroxide and perhalic acid is preferable as the oxidizing agent for preprocessing. In a case where the surface of an inorganic substance such as SiO₂ or Al₂O₃ coexists with the electric conductor surface, at least one selected from the group consisting of hydrogen peroxide and perhalic acid is also preferable from the viewpoint of processing the electric conductor surface without damaging the inorganic substance.

The oxidizing agent for preprocessing may be used alone or in combination of two or more kinds thereof.

The electric conductor surface may be subjected to ozone processing, or may be subjected to processing with an oxidizing agent for preprocessing after the ozone processing.

The electric conductor surface which has been subjected to at least one of the preprocessing with the oxidizing agent for preprocessing or the ozone processing is modified with a hydroxyl group.

The substrate used in the method for manufacturing a processed substrate according to the present embodiment may be a substrate having a surface including two or more regions formed of different materials, in which at least one region of the two or more regions has an electric conductor surface.

In a case of the substrate in which at least one region has an electric conductor surface, two or more regions may have an electric conductor surface. In a case of the substrate in which two or more regions have an electric conductor surface are present, these regions may have electric conductors that are the same as or different from each other.

Examples of the region in which the contact angle of water tends to be less (preferably, the surface free energy tends to be greater) than that of the other region between the two or more regions include a region having no electric conductor surface (for example, a region formed of an insulator (hereinafter, referred to as “insulator region”). The surface of the substrate to be processed may include one or two or more insulator regions. In a case where the surface includes two or more insulator regions, these regions may be formed of materials that are the same as or different from each other.

It is preferable that the surface of the substrate to be processed includes one or more regions having an electric conductor surface and one or more insulator regions.

The insulator constituting the insulator region is formed of an insulating compound. Examples of the insulating compound include an oxide such as aluminum oxide (Al₂O₃), titanium oxide (TiO₂), zirconium oxide (ZrO₂), hafnium oxide (HfO₂), tantalum oxide (Ta₂O₅), silicon oxide (SiOx (1≤x≤2), fluorine-containing silicon oxide (SiOF), or carbon-containing silicon oxide (SiOC); a nitride such as silicon nitride (SiN) or boron nitride (BN); a carbide such as silicon carbide (SiC); a carbonitride such as silicon carbonitride (SiCN); an oxynitride such as silicon oxynitride (SION); an oxycarbonitride such as silicon oxycarbonitride (SiOCN); and an insulating resin such as polyimide, polyester, or a plastic resin.

The surface of the substrate to be processed may include two or more regions having an electric conductor surface, and the materials of the proximate regions among the two or more regions may be different from each other.

In a case where the surface to be processed includes two regions, the surface to be processed may include a first region having an electric conductor surface and a second region (for example, an insulator region) formed of a material different from the material of the first region and adjacent to the first region. In this case, “proximity regions” may be the first region and the second region.

The first region and the second region may or may not be divided into a plurality of regions.

In a case where the surface to be processed includes three or more regions, the surface to be processed may include a first region having an electric conductor surface, a second region (for example, an insulator region) formed of a material different from the material of the first region and adjacent to the first region, and a third region formed of a material different from the material of the second region and adjacent to the second region. In such a case, “proximity regions” may be the first region and the second region (that is, adjacent regions) or the first region and the third region (that is, the regions separated by a region,.

Further, in a case where the first region and the third region are formed of materials that are not different from each other (that is, both the first region and the third region have an electric conductor surface), the “proximity regions” are the first region and the second region, or the second region and the third region (that is, adjacent regions).

The first region, the second region, and the third region may or may not be divided into a plurality of regions.

The same concept can be applied to a case where the surface to be processed includes the fourth or higher region.

The upper limit of the number of regions formed of different materials is not particularly limited as long as the effects of the present invention are not impaired, and for example, the upper limit thereof is 7 or less or 6 or less and typically 5 or less.

### (Method for Processing Substrate)

A method for processing a substrate according to a second aspect of the present invention is a method including a step of exposing a surface of a substrate to a surface modifier containing a compound (A) having a bonding property to the substrate (exposing step), and a step of cleaning the substrate after the exposure with a cleaning liquid to form a film while controlling the compound (A) in a plane direction and a height direction of the substrate (cleaning step).

In the method for processing a substrate, the cleaning liquid in which a distance Ra between a Hansen solubility parameter of the compound (A) and a Hansen solubility parameter of the cleaning liquid satisfies a relationship of (Ra)²≤128 is selected and used.

The exposing step and the cleaning step in the method for processing a substrate are the same as in the sections of <Exposing step> and <Cleaning step> in the above-described embodiment of (Method for manufacturing processed substrate) above.

According to the method for processing a substrate of the present aspect, the target substrate surface can be modified in a case where the method includes a step of exposing a surface of a substrate to a surface modifier containing a compound (A) having a bonding property to the substrate, and a step of cleaning the substrate after the exposure with a cleaning liquid to form a film while controlling the compound (A) in a plane direction and a height direction of the substrate.

In addition, in a case where the cleaning liquid in which the distance Ra between the Hansen solubility parameter of the compound (A) and the Hansen solubility parameter of the cleaning liquid satisfies a relationship of (Ra)²≤128 is selected and used, the cleaning removability of the surplus compound (A) is enhanced, and a modified layer having a uniform thickness can be formed.

### (Pattern Formation Method)

A pattern formation method according to a third aspect of the present invention is a method including a step of forming an atomic layer on a surface of a region of the processed substrate, which is manufactured by the manufacturing method according to the first aspect, where the surface modifier is not formed into a film, by forming a thin film using a vapor deposition method.

### <Step of Forming Atomic Layer by Forming Thin Film Using Vapor Deposition Method>

In the present step, an atomic layer is formed on a surface of a region of the processed substrate, which is manufactured by the method for manufacturing a processed substrate according to the above-described embodiment, where the surface modifier is not formed into a film, by forming a thin film using a vapor deposition method. For example, in FIG. 2, an atomic layer is formed on the surface of the region A of the processed substrate 100 after cleaning by forming a thin film using a vapor deposition method.

The vapor deposition method is a method using a gas containing a raw material for a thin film, and a method of forming a thin film by using a chemical reaction in a gas phase is preferably used.

Examples of the vapor deposition method include an atomic layer deposition (ALD) method, a chemical vapor deposition (CVD) method, a physical vapor deposition (PVD) method, a pulse laser deposition (PLD) method, a molecular beam epitaxy (MBE) method, and an ion plating (IP) method. Among these, an ALD method or a CVD method is preferable, and an ALD method is more preferable.

Examples of the CVD method include thermal CVD, plasma CVD, photo CVD, reduced pressure CVD, laser CVD, and metal organic CVD (MOCVD).

Examples of the ALD method include a thermal ALD method and a plasma ALD method.

Examples of the atomic layer (Y) to be formed include a metal layer, a metal oxide layer, a metal nitride layer, a non-metal oxide layer, a non-metal nitride layer, a metal-non-metal oxide layer, and a metal-non-metal nitride layer.

### [in Regard to Formation of Atomic Layer by ALD Method]

As the vapor deposition method of the present embodiment, an ALD method is preferable.

The substrate surface in the region where the surface modifier is formed into a film has selectively improved water repellency as compared with the surface of the region where the surface modifier is not formed into a film. As a result, the deposition amount of the material forming a film can be made to be different region-selectively on the substrate surface between the two or more regions. The selective improvement of the water repellency can be confirmed by measuring the contact angle of water with respect to the surface of the region.

Specifically, the region having a substrate surface among the two or more regions is difficult to adsorb (preferably chemically adsorb) the atomic layer forming material by the ALD method.

As a result, a difference in the deposition amount of the atomic layer forming material occurs between the two or more regions. That is, the deposition amount of the atomic layer forming material by the ALD method is region-selectively different. Specifically, the deposition amount of the atomic layer forming material in the region having a substrate surface is lower than the deposition amount in the insulator region. Examples of the chemical adsorption of the atomic layer forming material include chemical adsorption of a hydroxyl group applied to the substrate surface by performing preprocessing.

Among the two or more regions, as a region where the contact angle of water tends to be greater (preferably, the surface free energy decreases) than that of other regions, a region containing at least one selected from the group consisting of W, Co, Al, Ni, Ru, and Cu is an exemplary example. The region having a substrate surface may be a region containing these.

Among the two or more regions, as a region where the contact angle of water tends to be less (preferably, the surface free energy increases) than that of other regions, a region containing at least one selected from the group consisting of Si, Al₂O₃, SiN, SiOx, Ge, SiGe, TEOS, a Low-k material, and ILD is an exemplary example. The insulator region may be a region formed of a material containing these in addition to the insulating compound.

The atomic layer formation method using the ALD method is not particularly limited, and a thin-film formation method carried out by adsorption (preferably chemical adsorption) using at least two gas phase reactants (hereinafter, simply referred to as “precursor gas”) is preferable.

Specifically, a method including the following steps (a) and (b) and repeating the following steps (a) and (b) at least once (one cycle) until a desired film thickness is obtained is an exemplary example.

The method includes a step (a) of exposing the surface-modified substrate to a pulse of a first precursor gas and a step (b) of exposing the substrate to a pulse of a second precursor gas after the step (a).

The method may or may not include a plasma processing step and a step of removing or exhausting (purging) the first precursor gas and a reactant thereof with a carrier gas, the second precursor gas, or the like after the step (a) and before the step (b). The method may or may not include a plasma processing step and a step of removing or purging the second precursor gas and a reactant thereof with a carrier gas or the like after the step (b).

Examples of the carrier gas include an inert gas such as nitrogen gas, argon gas, or helium gas.

It is preferable that each pulse for each cycle and each layer to be formed are self-controlled and more preferable that each layer to be formed is a monoatomic layer. The film thickness of the monoatomic layer can be set to, for example, 5 nm or less, preferably 3 nm or less, more preferably 1 nm or less, and still more preferably 0.5 nm or less.

Examples of the first precursor gas include an organic metal, a metal halide, and a metal oxide halide, and specific examples thereof include tantalum pentaethoxide, tetrakis (dimethylamino) titanium, pentakis (dimethylamino) tantalum, tetrakis (dimethylamino) zirconium, tetrakis(dimethylamino) hafnium, tetrakis(dimethylamino) silane, copper hexafluoroacetylacetonate vinyltrimethylsilane, Zn(C₂H₅)₂, Zn(CH₃)₂, trimethyl aluminum (TMA), TaCl₅, WF₆, WOCl, CuCl, ZrCl₄, AlCl, Al(CH₃)₃, TiCl₄, SiCl₄, and HfCl₄.

Examples of the second precursor gas include a precursor gas capable of decomposing the first precursor and a precursor gas capable of removing the ligand of the first precursor, and specific examples thereof include H₂O, H₂O₂, O₂, O₃, NH₃, H₂S, H₂Se, PH₃, AsH₃, C₂H₄, and Si₂H₆.

The exposure temperature in the step (a) is not particularly limited, but is, for example, 100° C. or higher and 800° C. or lower, preferably 150° C. or higher and 650° C. or lower, more preferably 180° C. or higher and 500° C. or lower, and still more preferably 200° C. or higher and 375° C. or lower.

The exposure temperature in the step (b) is not particularly limited and may be a temperature substantially equal to or higher than the exposure temperature in the step (a).

The film to be formed using the ALD method is not particularly limited, and examples thereof include a film containing a pure element (such as Si, Cu, Ta, or W), a film containing an oxide (such as SiO₂, GeO₂, HfO₂, ZrO₂, Ta₂O₅, TiO₂, Al₂O₃, ZnO, SnO₂, Sb₂O₅, B₂O₃, In₂O₃, or WO₃), a film containing a nitride (such as Si₃N₄, TiN, AlN, BN, GaN, or NbN), a film containing a carbide (such as SiC), a film containing a sulfide (such as CdS, ZnS, MnS, WS2, or PbS), a film containing a selenide (such as CdSe or ZnSe), a film containing a phosphide (GaP or InP), a film containing an arsenide (such as GaAs or InAs), and a mixture thereof.

In the method of the present embodiment, an atomic layer is formed on the processed substrate which has been surface-modified using a surface modifier and manufactured by the manufacturing method according to the first aspect, by an ALD method. In the surface-modified processed substrate, the water repellency of the region having a substrate surface is selectively improved. Therefore, in the region having a substrate surface, the deposition of the atomic layer forming material by the ALD method is inhibited. As a result, in the region having a substrate surface, the deposition amount of the atomic layer forming material by the ALD method is less than that of the insulator region. In this manner, a film can be region-selectively formed by an ALD method on the insulator region,

According to the pattern formation method of the present embodiment, an atomic layer can be formed on the surface of the region of the processed substrate, which is manufactured by the manufacturing method according to the first aspect, where the surface modifier is not formed into a film, by forming a thin film using a vapor deposition method. Therefore, the pattern formation method of the present embodiment can be suitably applied to selective atomic layer formation.

### (Cleaning Liquid)

The cleaning liquid according to a fourth aspect of the present invention is a cleaning liquid used in the method according to the first aspect or the second aspect.

Such a cleaning liquid is the same as in the description of <<In regard to cleaning liquid>> in the above-described embodiment of (Method for manufacturing processed substrate) above.

The cleaning liquid of the present embodiment may include only one or two or more kinds of organic solvents (S1).

As the organic solvents (S1), decane, tetradecane, cyclohexane, 2-methoxy-1-methylethyl acetate, isobutanol, 1-octanol, 2-ethyl-1-hexanol, dibutyl ether, acetone, cyclopentanone, 2,6-dimethyl-4-heptanone, and 1-methoxy-2-propanol are preferable.

The content of the component (S1) in the cleaning liquid is not particularly limited as long as the distance Ra between the Hansen solubility parameter of the compound (A) and the Hansen solubility parameter of the cleaning liquid satisfies the relationship of (Ra)²≤128, but is preferably 50% by mass or greater, more preferably 60% by mass or greater, and still more preferably 70% by mass or greater, and may be 100% by mass with respect to the total mass of the cleaning liquid.

The cleaning liquid of the present embodiment may contain an organic solvent (S2) (hereinafter, also referred to as “component (S2)”) other than the component (S1). The component (S2) is not particularly limited, and an organic solvent having a miscibility with the component (S1) can be used.

The cleaning liquid may contain optional components in addition to the organic solvent. Examples of the optional components include water and impurities.

The cleaning liquid of the present embodiment may contain water. The water may contain a trace amount of components that are inevitably mixed. As the water, water that has been subjected to purification processing, such as distilled water, ion exchange water, or ultrapure water, is preferable, and ultrapure water typically used for manufacture of semiconductors is more preferable.

In a case where the cleaning liquid contains water, the content of water is preferably in a range of 0.01% to 25% by mass, more preferably in a range of 0.03% to 20% by mass, and still more preferably in a range of 0.05% to 15% by mass with respect to the total mass of the cleaning liquid.

The cleaning liquid of the present embodiment may contain no water.

The cleaning liquid of the present embodiment may include metal impurities including metal atoms such as a Fe atom, a Cr atom, an Ni atom, a Zn atom, a Ca atom, and a Pb atom.

The total content of the metal atoms in the cleaning liquid of the present embodiment is preferably 100 ppt by mass or less with respect to the total mass of the cleaning liquid. The lower limit of the total content of the metal atoms is preferably as low as possible, but is, for example, 0.001 ppt by mass or greater. The total content of the metal atoms is, for example, 0.001 ppt by mass or greater and 100 ppt by mass or less.

In a case where the total content of the metal atoms is set to be less than or equal to the upper limits of the above-described preferable ranges, the removal performance of the surplus surface modifier is improved. It is considered that in a case where the total content of the metal atoms is set to be greater than or equal to the lower limits of the above-described preferable ranges, the metal atoms are unlikely to be present in a state of being released in the system and unlikely to adversely affect the manufacturing yield of the entire target to be cleaned.

The content of the metal impurities can be adjusted, for example, by purification processing such as filtering. The purification processing such as filtering may be performed on a part or all of the raw materials before the cleaning liquid is prepared, or may be performed after the cleaning liquid is prepared.

The cleaning liquid of the present embodiment may include, for example, organic substance-derived impurities (organic impurities). The total content of the organic impurities in the cleaning liquid of the present embodiment is preferably 5,000 ppm by mass or less. The lower limit of the content of the organic impurities is preferably as low as possible, and the lower limit is, for example, 0.1 ppm by mass or greater, The total content of the organic impurities is, for example, 0.1 ppm by mass or greater and 5,000 ppm by mass or less.

The cleaning liquid of the present embodiment may include, for example, an object to be counted with a size counted by a light scattering type in-liquid particle counter. The size of the object to be counted is, for example, 0.04 μm or greater. The number of the objects to be counted in the cleaning liquid of the present embodiment is, for example, 1,000 or less per mL of the cleaning liquid, and the lower limit is, for example, 1 or greater. It is considered that in a case where the number of the objects to be counted in the cleaning liquid is in the above-described range, the removal performance of the surplus surface modifier is improved.

A method of storing the cleaning liquid of the present embodiment is not particularly limited, and storage containers known in the related art can be used. In order to ensure the stability of the cleaning liquid, the void ratio in the container in a case of storing the cleaning liquid in the container and the kind of gas for filling the void portion may be appropriately set. For example, the void ratio in the storage container is about 0.01% to 30% by volume.

According to the cleaning liquid of the present embodiment, in the method according to the first aspect or the second aspect, since the cleaning liquid in which the distance Ra between the Hansen solubility parameter of the compound (A) and the Hansen solubility parameter satisfies a relationship of (Ra)²≤128 is selected and used, the component (A) excessively deposited after the exposure to the surface modifier can be removed at a high cleaning removal rate.

### EXAMPLES

Hereinafter, the present invention will be described in more detail based on examples, but the present invention is not limited to these examples.

The substrate, the surface modifier, and the cleaning liquid used in the present example are shown below.

### (Preprocessing of Substrate)

As the substrate, a coupon prepared by cutting a blanket substrate having a copper film with a thickness of 200 nm on an 8-inch silicon substrate into 2 cm×2 cm was used. As the substrate used, a substrate processed with diluted hydrofluoric acid was used in all examples.

Specifically, each substrate was immersed in an HF aqueous solution with a concentration of 25 ppm at 25° C. for 1 minute to perform preprocessing. Further, the contact angle of the substrate surface after the preprocessing with respect to water, which was measured by a method described below, was 30.0°.

After the preprocessing, each substrate was cleaned with deionized water for 1 minute. Each substrate after the cleaning with water was dried by a nitrogen stream.

### (Preparation of Surface Modifier)

As a surface modifier, 100% by mass of octadecanethiol (ODT) was used.

### (Preparation of Cleaning Liquid)

As a cleaning liquid, 100% by mass of the following organic solvent (S1) was used. In addition, the reference cleaning liquid was set to 100% by mass of isopropanol,
(S1)-1: acetone
(S1)-2: propylene glycol monomethyl ether
(S1)-3: decane
(S1)-4: tetradecane
(S1)-5: cyclohexane
(S1)-6:1-octanol
(S1)-7: isobutanol
(S1)-8:2-ethyl-1-hexanol
(S1)-9: dibutyl ether
(S1)-10:2,6-dimethyl-4-heptanone
(S1)-11: cyclopentanone
(S1)-12: propylene glycol monomethyl ether acetate

As the organic solvent (S1), an organic solvent in which a distance Ra between the Hansen solubility parameter of the ODT and the Hansen solubility parameter of the organic solvent (S1) satisfied a relationship of (Ra)²≤128 was selected as a cleaning liquid.

### [Method for Calculating (Ra)²]

(Ra)² was calculated using each parameter value listed in Table 1, for example, in a case where (S1)-1 was used.

TABLE 1

| | Composition | δ_{d} | δₚ | δₕ |
|---|---|---|---|---|
| Surface modifier | ODT | 16.4 | 2.3 | 2.6 |
| Cleaning liquid | (S1)-1 | 15.7 | 9.1 | 6.5 |

$${( Ra )}^{2} = {( {δ}_{dS} - {δ}_{dA} )}^{2} + {( {δ}_{pS} - {δ}_{pA} )}^{2} + ( {δ}_{hS} - {δ}_{hA} )$$

[Here, δ_{dS} and δ_{dA} are dispersion terms, δ_{pS} and δ_{pA} are polarity terms, and δ_{hS} and δ_{hA} are hydrogen bond terms.]

(Ra)² was calculated in the following manner using Mathematical Equation (1) in a case where (S1)-1 was used.

$${( Ra )}^{2} = {( 15.7 - 16.4 )}^{2} + {( 9.1 - 2.3 )}^{2} + {( 6.5 - 2.6 )}^{2} = 61.9$$

(Ra)² in each of the cases where (S1)-2 to (S1)-12 and isopropanol were used was also calculated in the same manner as described above. Table 2 lists each parameter value and (Ra)².

TABLE 2

| Cleaning | | | | | |
|---|---|---|---|---|---|
| liquid | Organic solvent | δ_{d} | δₚ | δₕ | (Ra)² |
| (S1)-1 | Acetone | 15.7 | 9.1 | 6.5 | 61.9 |
| (S1)-2 | Propylene glycol monomethyl | 16.4 | 6.7 | 6.1 | 31.6 |
| | ether | | | | |
| (S1)-3 | Decane | 15.6 | 0.1 | 0.1 | 11.7 |
| (S1)-4 | Tetradecane | 15.8 | 0.1 | 0.1 | 11.5 |
| (S1)-5 | Cyclohexane | 16.6 | 0.1 | 0.1 | 11.1 |
| (S1)-6 | 1-Octanol | 16.1 | 4.4 | 12.3 | 98.6 |
| (S1)-7 | Isobutanol | 15.5 | 6.1 | 12.5 | 113.3 |
| (S1)-8 | 2-Ethyl-1-hexanol | 15.5 | 3.1 | 3.0 | 64.7 |
| (S1)-9 | Dibutyl ether | 18.0 | 8.6 | 5.1 | 1.61 |
| (S1)-10 | 2,6-Dimethyl-4-heptanone | 15.5 | 4.2 | 2.5 | 4.43 |
| (S1)-11 | Cyclopentanone | 18.0 | 8.6 | 5.1 | 48.5 |
| (S1)-12 | Propylene glycol monomethyl | 16.3 | 7.5 | 12.5 | 125.1 |
| | ether acetate | | | | |
| Reference | Isopropanol | 15.5 | 7.2 | 12.8 | 128.9 |

### <Method for Manufacturing Processed Substrate>

### Examples 1 to 12 and Comparative Example 1

A processed substrate was obtained by the manufacturing method of each example, including an exposing step of exposing the surface of the substrate to the surface modifier ODT and a cleaning step of cleaning the substrate after the exposing step with a cleaning liquid. Specifically, the processed substrate was obtained as follows.

### Exposing Step:

The substrate after being dried in the above-described (preprocessing of the substrate) was immersed in the surface modifier ODT at 25° C. for 1 minute to modify the surface of the substrate.

Further, the contact angle of the substrate surface with respect to water after the exposing step, which was measured by a method described below, was 104.5°.

### Cleaning Step:

The substrate after the exposing step was subjected to cleaning processing by being immersed in each of the above-described cleaning liquids at 25° C. for 1 minute.

The substrate after the cleaning processing was cleaned with ion exchange distilled water at 25° C. for 1 minute and dried by a nitrogen stream, thereby manufacturing a surface-modified processed substrate.

### <Evaluation>

The ODT residual rate and the contact angle of water were measured using the method described below for the processed substrate manufactured by the manufacturing method of each example.

### [ODT Residual Rate]

The ODT residual rates of the processed substrates manufactured in Examples 1 to 12 and Comparative Example 1 were measured,

The ODT residual rate was calculated from the area ratio of molecules of the surface modifier ODT covering the monolayer surface, by observing the processed substrate from above, which was manufactured in each example, with an atomic force microscope (AFM) and detecting the molecules of the surface modifier ODT present (that is, deposited on the monolayer) at a height from the substrate surface, which was greater than the thickness of the monolayer in which the molecules of the surface modifier ODT formed on the substrate were arranged. The results are listed in Table 3.

Further, the ODT residual rate (%) listed in Table 3 is a value obtained by performing AFM observation at optional three points on the surface of the processed substrate, calculating the ODT residual rate of each point in the observation range, and averaging the calculated values.

The ODT residual rate was determined by calculating the proportion (%) of an area occupied by the surplus portion 24 to the total area of the AFM observation image (observation range of 1 μm×1 μm).

The thickness L of the monolayer in which the molecules of the surface modifier ODT formed on the substrate were arranged was set to 2 nm.

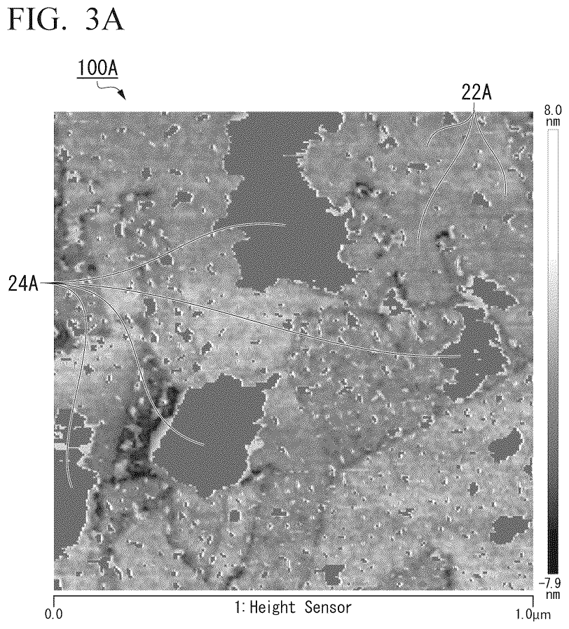

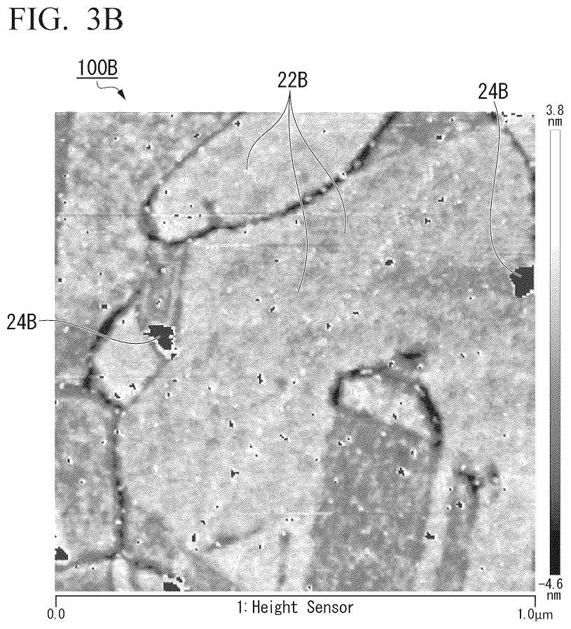

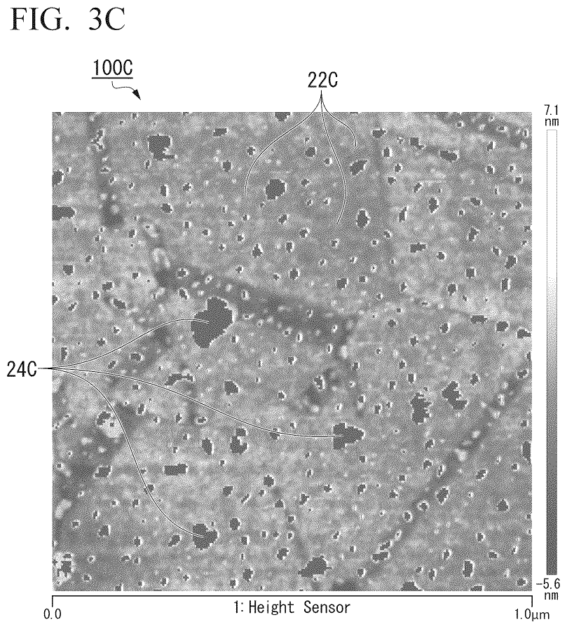

FIG. 3A is an AFM observation image (observation range: 1 μm×1 μm) of the substrate surface immediately after the exposing step. FIG. 3B is an AFM observation image (observation range: 1 μm×1 μm) of the surface of the processed substrate manufactured in Example 11. FIG. 3C is an AFM observation image (observation range: 1 μm×1 μm) of the surface of the processed substrate manufactured in Comparative Example 1.

In the AFM observation image shown in FIG. 3A, the reference numeral 100A denotes a processed substrate. The reference numeral 22A denotes a monolayer portion in which the surface modifier ODT is directly bonded to the substrate surface. The reference numeral 24A denotes a surplus portion in which the surface modifier ODT is deposited on a monolayer portion 22A.

In the AFM observation image shown in FIG. 3B, the reference numeral 100B denotes a processed substrate. The reference numeral 22B denotes a monolayer portion in which the surface modifier ODT is directly bonded to the substrate surface. The reference numeral 24B denotes a surplus portion in which the surface modifier ODT is deposited on a monolayer portion 22B.

In the AFM observation image shown in FIG. 3C, the reference numeral 100C denotes a processed substrate. The reference numeral 22C represents a monolayer portion in which the surface modifier ODT is directly bonded to the substrate surface. The reference numeral 24C denotes a surplus portion in which the surface modifier ODT is deposited on a monolayer portion 22C.

TABLE 3

| | | ODT |
|---|---|---|
| | | residual rate |
| | Cleaning liquid | (%) |
| Example 1 | (S1)-1 | 4.6 |
| Example 2 | (S1)-2 | 4.0 |
| Example 3 | (S1)-3 | 1.8 |
| Example 4 | (S1)-4 | 0.040 |
| Example 5 | (S1)-5 | 1.6 |
| Example 6 | (S1)-6 | 7.4 |
| Example 7 | (S1)-7 | 4.4 |
| Example 8 | (S1)-8 | 5.9 |
| Example 9 | (S1)-9 | 3.6 |
| Example 10 | (S1)-10 | 3.8 |
| Example 11 | (S1)-11 | 1.4 |
| Example 12 | (S1)-12 | 3.4 |
| Comparative | Reference | 8.2 |
| Example 1 | | |

As shown in the results listed in Table 3, it can be seen that the cleaning liquids used in the manufacturing methods of Examples 1 to 12 have a lower ODT residual rate, that is, higher cleaning removability of the surplus ODT, as compared with the reference cleaning liquid used in the manufacturing method of Comparative Example 1.

In particular, in the manufacturing methods of Examples 3 to 5, it can be seen that the ODT residual rate is particularly low, and the cleaning removability of the surplus ODT is significantly improved.

### [Contact Angle of Water]

The contact angles of the processed substrates manufactured in Examples 1 to 12 and Comparative Example 1 with respect to water were measured.

The contact angle of water was measured as a contact angle of water 2 seconds after dropwise addition of a pure water liquid droplet (2.0 μL) onto the surface of the surface-modified substrate using Dropmaster 700 (manufactured by Kyowa Interface Science Co., Ltd.). The results are listed in Table 4.

TABLE 4

| | | Contact angle |
|---|---|---|
| | | of water |
| | Cleaning liquid | (° C.) |
| Reference | (Immediately after | 104.5 |
| Example | exposing step) | |
| Example 1 | (S1)-1 | 105.0 |
| Example 2 | (S1)-2 | 103.9 |
| Example 3 | (S1)-3 | 106.4 |
| Example 4 | (S1)-4 | 109.9 |
| Example 5 | (S1)-5 | 104.4 |
| Example 6 | (S1)-6 | 107.2 |
| Example 7 | (S1)-7 | 104.6 |
| Example 8 | (S1)-8 | 102.7 |
| Example 9 | (S1)-9 | 104.4 |
| Example 10 | (S1)-10 | 104.1 |
| Example 11 | (S1)-11 | 105.1 |
| Example 12 | (S1)-12 | 104.3 |
| Comparative | Reference | 104.6 |
| Example 1 | | |

As shown in the results listed in Table 4, it was confirmed that in the manufacturing methods of Examples 1 to 12, the contact angle of the dried processed substrate after the cleaning step with respect to water was in a range of 102.7° to 109.9°, which was approximately the same as the contact angle of 104.5° of the substrate surface after the exposing step with respect to water.

Therefore, since it is clear that the ODT layer is maintained at a constant thickness on the substrate surface before and after the cleaning processing, the results listed in Table 4 suggest that only the surplus ODT is efficiently removed.

While preferred examples of the present invention have been described and illustrated above, it should be understood that these are exemplary of the present invention and are not to be considered as limiting. Additions, omissions, substitutions, and other modifications can be made without departing from the scope of the present invention. The present invention is not limited by the description above, but is limited only by the appended claims.

### REFERENCE SIGNS LIST

10 Substrate
20 Compound (A)
22 Monolayer portion
24 Surplus portion
100 Processed substrate
220 Surface modifier layer
224 Surface modifier layer

What is claimed is:

1. A method for manufacturing a processed substrate having a surface in which at least a part of a region is modified, the manufacturing method comprising:
exposing a surface of a substrate to a surface modifier containing a compound (A) having a bonding property to the substrate; and
cleaning the substrate after the exposure with a cleaning liquid and performing film formation while controlling the compound (A) in a plane direction and a height direction of the substrate to obtain a processed substrate,
wherein the cleaning liquid in which a distance Ra between a Hansen solubility parameter of the compound (A) and a Hansen solubility parameter of the cleaning liquid satisfies a relationship of (Ra)²≤128 is selected and used.

2. The method for manufacturing a processed substrate according to claim 1, wherein the compound (A) is an alkylthiol compound.

3. The method for manufacturing a processed substrate according to claim 2, wherein the cleaning liquid contains at least one organic solvent selected from the group consisting of an alkane having 6 or more carbon atoms, an alkylene glycol monoalkyl ether acetate having 6 or more carbon atoms, an alcohol having 4 or more carbon atoms, an ether having 8 or more carbon atoms, and a ketone having 3 or more carbon atoms.

4. The method for manufacturing a processed substrate according to claim 3, wherein a content of the organic solvent in the cleaning liquid is 70% by mass or greater with respect to a total mass of the cleaning liquid.

5. A method for processing a substrate, comprising:
exposing a surface of a substrate to a surface modifier containing a compound (A) having a bonding property to the substrate; and
cleaning the substrate after the exposure with a cleaning liquid and performing film formation while controlling the compound (A) in a plane direction and a height direction of the substrate,
wherein the cleaning liquid in which a distance Ra between a Hansen solubility parameter of the compound (A) and a Hansen solubility parameter of the cleaning liquid satisfies a relationship of (Ra)²≤128 is selected and used.

6. A pattern formation method comprising:
manufacturing a processed substrate having a surface in which at least a part of a region is modified by the manufacturing method according to claim 1, and
forming an atomic layer on a surface of a region of the processed substrate, wherein the surface modifier is not formed into a film, by forming a thin film using a vapor deposition method.

7. (canceled)

8. (canceled)
